(19) United States
(12) Patent Application Publication
(10) Pub. No.: US 2026/0304639 A1
(43) Pub. Date: Oct. 1, 2026

(54) CIRCUIT BOARD AND MANUFACTURING METHOD OF CIRCUIT BOARD

(71) Applicant: SAMSUNG ELECTRO-MECHANICS CO., LTD., Suwon-si (KR)

(72) Inventors: Seong Ho Choi, Suwon-si (KR); Sukchang Hong, Suwon-si (KR)

(73) Assignee: SAMSUNG ELECTRO-MECHANICS CO., LTD., Suwon-si (KR)

(21) Appl. No.: 19/272,699

(22) Filed: Jul. 17, 2025

(30) Foreign Application Priority Data
Mar. 26, 2025 (KR) 10-2025-0038611

(51) Int. Cl. H05K 3/24; H05K 3/10; H05K 3/28

(52) U.S. Cl. CPC H05K 3/243; H05K 3/108; H05K 3/28

(57) ABSTRACT

A circuit board includes a first insulating layer and a lower pad exposed from the first insulating layer, with the exposed surface recessed below the surface of the first insulating layer. A second insulating layer is formed on the first insulating layer, and an upper pad is disposed on the second insulating layer. A via penetrates the second insulating layer and electrically connects the lower pad and the upper pad. A plating layer, such as a nickel and gold layer, is disposed on the upper pad. The circuit board structure may enable reliable electroplating without requiring a separate bus line by utilizing a seed copper layer from a detachable core.

### CROSS-REFERENCE TO RELATED APPLICATION

This application claims priority to and the benefit of Korean Patent Application No. 10-2025-0038611 filed with the Korean Intellectual Property Office on Mar. 26, 2025, the entire contents of which are incorporated herein by reference.

### BACKGROUND OF THE INVENTION

### (a) Field of the Invention

The present disclosure relates to a circuit board and manufacturing method thereof.

### (b) Description of the Related Art

In a semiconductor chip or printed circuit board (PCB) manufacturing fields, various manufacturing methods are developed to meet the demands for miniaturization, high density, and high performance. In particular, a coreless method, unlike an existing core-based PCB manufacturing method, forms a circuit pattern without a central core substrate and then laminates an insulating layer, which may have the advantages of reducing thickness and improving signal transmission characteristics.

Recently, PCB manufacturing technology utilizing dual detach cores has been attracting attention, and this technology may provide the advantage of more effectively reducing the thickness of the substrate by temporarily using the cores during the manufacturing process and then separating them. Additionally, external connection terminals such as ball pads or bond fingers located on the top of the circuit board may require electrolytic gold plating for reliable bonding, which may play an important role in improving the electrical characteristics and durability of the package.

### SUMMARY OF THE INVENTION

The present disclosure may provide a circuit board and a manufacturing method thereof, which may efficiently perform a plating process without a separate bus line design and removal process by utilizing a seed copper layer of a separate core in a manufacturing process of a semiconductor chip or a printed circuit board.

The object of the present disclosure is not limited to the above-described object, and it may be expanded in various ways in the range of the ideas and the areas of the present disclosure.

In one aspect, a circuit board includes a lower pad exposed from the first insulating layer, wherein the exposed surface has a depth recessed from a surface of the first insulating layer; a second insulating layer disposed on the first insulating layer; an upper pad disposed on the second insulating layer; a via penetrating the second insulating layer, and connecting the lower pad and the upper pad; and a plating layer disposed on the upper pad.

The plating layer may include a nickel plating layer and a gold plating layer.

The circuit board may further include a protective layer disposed on the second insulating layer and covering the upper pad.

The protective layer may be penetrated to expose a portion of the upper pad, and the plating layer is disposed on the exposed upper pad.

The first insulating layer and the second insulating layer may include different insulating materials.

The upper pad may include a first upper pad and a second upper pad disposed apart from each other on the second insulating layer, and the first upper pad may be connected to the via.

The plating layer may be disposed on the first upper pad.

The lower pad may include a first lower pad and a second lower pad spaced from each other by the first insulating layer, and the first lower pad may be connected to the via.

The first lower pad may include a ball pad.

The second lower pad may include a fiducial mark.

The lower pad may have an extension portion that is larger than a width of a portion embedded in the first insulating layer and extends on the first insulating layer.

In another aspect, a manufacturing method of a circuit board includes forming a first insulating layer on a copper layer of a base substrate; forming a lower pad that penetrates the first insulating layer and is connected to the copper layer; forming a second insulating layer on the first insulating layer; forming a via penetrating the second insulating layer and connected to the lower pad, and an upper pad disposed on the second insulating layer and connected to the via; and forming a plating layer on the upper pad by applying electricity to the copper layer.

The manufacturing method may further include removing the copper layer by etching.

The manufacturing method may further include removing the copper layer by etching.

The base substrate may include a detachable core substrate.

The forming the lower pad may include forming an extension portion that is larger than a width of a portion embedded in the first insulating layer and extends on the first insulating layer.

The manufacturing method may further include forming a protective layer to cover the upper pad on the second insulating layer.

The forming the plating layer may include conducting electroplating on an area where the upper pad is exposed by patterning the protective layer.

The forming the plating layer may include plating a nickel plating layer and a gold plating layer.

According to the present disclosure, a plating process may be performed by utilizing a seed copper layer of a separate core without a process of designing and removing a separate bus line, so that the complexity of circuit design may be significantly reduced.

According to the present disclosure, the problem of exposing a cut pattern on a unit cross-section that occurs in the conventional method may be eliminated, so that the appearance and structural completeness of the circuit board may be improved, and the process time and cost required for designing and removing bus line may be reduced.

In addition, the manufacturing process may be simplified by eliminating the need for complex design processes such as additional drilling work or line bypass arrangements, which may improve mass productivity and reduce defect rates.

### BRIEF DESCRIPTION OF THE DRAWINGS

FIG. 1 is a cross-sectional view schematically illustrating a structure of a circuit board according to an embodiment.

FIGS. 2 to 9 are process cross-sectional views illustrating a method for manufacturing a circuit board according to an embodiment.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification.

In order to clearly describe the present disclosure, parts unrelated to the description are omitted in the drawings, and the same reference numerals are designated to the same or similar elements throughout the specification. The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

Furthermore, it will be understood that when an element such as a layer, layer, region, or substrate is referred to as being “on” another element, it can be directly on the other element or intervening elements may also be present. On the contrary, when an element is referred to as being “directly on” another element, there are no intervening elements present. In addition, these positional relationships are independent of the direction of gravity.

It will be further understood that terms “comprises/includes” or “have” used throughout the specification specify the presence of stated features, numerals, steps, operations, elements, parts, or a combination thereof, but do not preclude the presence or addition of one or more other features, numerals, steps, operations, elements, parts, or a combination thereof. Accordingly, unless explicitly stated otherwise, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more elements are not only directly connected, but two or more elements may be connected indirectly through other elements, physically connected as well as being electrically connected, or it may be referred to by different names depending on the location or function but may mean integral.

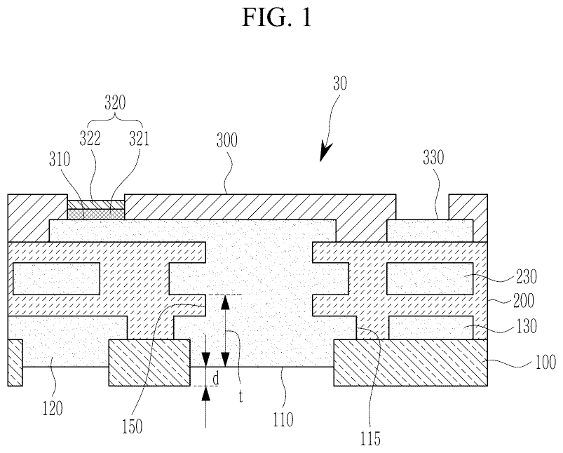

FIG. 1 is a cross-sectional view schematically illustrating a structure of a circuit board according to an embodiment.

Referring to FIG. 1, the circuit board 30 according to an embodiment includes a first insulating layer 100, lower pads (110, 120) formed by penetrating the first insulating layer 100 and exposed from the lower surface, a second insulating layer 200 laminated on the first insulating layer 100, and upper pads (310, 330) disposed on the second insulating layer 200. The lower pads may include a first lower pad 110 and a second lower pad 120, and the upper pads may include a first upper pad 310 and a second upper pad 330. In addition, the circuit board 30 includes a via 150 connecting the first upper pad 310 and the first lower pad 110, and a plating layer 320 composed of a nickel (Ni) layer 321 and a gold (Au) layer 322 may be formed on the first upper pad 310.

The first insulating layer 100 has upper and lower surfaces facing each other. The first insulating layer 100 may be composed of materials selected from PID (photosensitive interlayer dielectric), PPG (Pre-Preg), ABF (Ajinomoto Build-up Layer), RCC (Resin Coated Copper), etc. These materials each have unique properties and may be selected by considering thermal stability, mechanical strength, electrical insulation, and signal transmission characteristics.

The first lower pad 110 and the second lower pad 120 formed by penetrating the first insulating layer 100 may be made of a conductive metal such as copper (Cu), and may be exposed from the lower surface of the first insulating layer 100 and function as external electrical connection points.

An extension portion 115 may be disposed on the upper surface of the first insulating layer 100. The extension portion 115 may be integrally connected to a portion embedded in the first insulating layer 100 among the lower pads 110, 120. The extension portion 115 is formed wider than a basic width of the portion embedded in the first insulating layer 100 among the lower pads 110, 120 and may have a flat shape such as a circle or square. This extended structure may improve a mechanical bonding strength by increasing the contact area between the lower pads 110, 120 and the first insulating layer 100.

A first signal wiring 130 formed on the upper surface of the first insulating layer 100 is physically and electrically separated from the extension portion 115 to form an independent electric signal path. The first signal wiring 130 may be formed of a conductive metal, such as copper, and may provide electrical connections between various pads or components within the circuit board 30.

The exposed surfaces of the lower pads 110, 120 may be formed by recessing a depth (d) from the lower surface of the first insulating layer 100. This recessed structure may be formed through a flash etching process, and the depth (d) may be formed to be 2 μm or more to ensure stability when mounting components. The recessed structure has the effect of protecting the pad from external impact or mechanical stress by positioning the pad surface inward from the lower surface of the first insulating layer 100. In addition, this structure may improve the flatness and uniformity of the pad surface, thereby improving the bonding quality in the subsequent soldering process.

First, the lower pad 110 is formed integrally with the extension 115, so that even if the thickness of the circuit metal layer is lowered to reduce the substrate thickness, the minimum copper thickness (t) required for the mounting strength standard may be secured. This is a structural feature that may maintain mechanical reliability while implementing an ultra-thin circuit board.

For example, the first lower pad 110 and the second lower pad 120 may have different functional purposes. The first lower pad 110 may primarily function as a ball pad and serve as solder ball or an electrical connection point with other electronic components. On the other hand, the second lower pad 120 may be formed on each layer as a fiducial mark and may provide a reference so that the structure of each layer is aligned in the correct position.

The second insulating layer 200 disposed on the upper surface of the first insulating layer 100 may function as an intermediate layer for forming a multilayer circuit structure. The second insulating layer 200 may be made of a thermosetting resin such as an epoxy resin, a thermoplastic resin such as a polyimide, or a resin impregnated with a reinforcing material such as glass fiber or inorganic filler, for example, a prepreg. In addition, the second insulating layer 200 may include, but is not limited to, a thermosetting resin and/or a photocurable resin. By configuring the first insulating layer 100 and the second insulating layer 200 with different materials, it is possible to select optimized materials that meet the required characteristics of each layer, and the stability of the entire circuit board may be improved by controlling the thermal expansion coefficient and mechanical rigidity.

A via 150 formed by penetrating the second insulating layer 200 is a via filled with a conductive metal such as copper and may provide a vertical electrical connection between the first lower pad 110 and the first upper pad 310. The via 150 may be formed through laser drilling, mechanical drilling, or photolithography processes, and an inner wall of via 150 may be treated with uniform metal plating to ensure stable electrical connection characteristics.

On the second insulating layer 200, the first upper pad 310 and the second upper pad 330 may be disposed apart from each other. These upper pads 310, 330 may be formed of a conductive metal such as copper and may have a planar structure having a set area on the second insulating layer 200. The first upper pad 310 may be electrically connected to the first lower pad 110 through the via 150 to form an upper and lower signal path of the circuit board 30. The second upper pad 330 may provide an independent electrical path or be connected to other signal wiring.

A second signal wiring 230 may also be formed within the second insulating layer 200. The second signal wiring 230 provides electrical connection between the upper pads 310 and 320 or between other circuit elements, and may be designed with various widths and spacings to help control impedance or ensure signal integrity.

According to the embodiment illustrated in FIG. 1, the second insulating layer 200 includes two layers of insulating layers and two layers of circuit wiring layers are formed on these two layers of insulating layers; however, the present disclosure is not limited thereto and may include a greater number of build-up insulating layers and a greater number of build-up circuit wiring layers, which also fall within the scope of the present disclosure.

A protective layer 300 covering the first upper pad 310 and the second upper pad 330 may be formed on the second insulating layer 200. The protective layer 300 may be composed of a solder resist material and has photosensitivity, enabling precise patterning through exposure and development processes. The solder resist has excellent heat resistance, moisture resistance, and chemical resistance, so it can effectively protect the circuit from the external environment. The protective layer 300 is patterned to expose portions of the upper pads 310, 330, so as to provide electrical connection points to external components through the exposed areas.

The plating layer 320 including the nickel (Ni) plating layer 321 and the gold (Au) plating layer 322 may be formed on the exposed first upper pad 310. The nickel plating layer 321 may be formed with a thickness in the range of 2 μm to 5 μm and may act as a diffusion barrier between the copper pad and the gold plating layer. This may improve the long-term reliability of the joint by preventing the formation of intermetallic compounds between copper and gold. In addition, the nickel plating layer may provide mechanical strength, which may improve durability during wire bonding or soldering processes.

The gold plating layer 322 may be formed with a thin thickness, typically ranging from 0.05 μm to 0.3 μm, and constitutes the outermost surface. Gold has excellent oxidation resistance, which allows it to maintain long-term solderability on the pad surface. In addition, gold provides excellent electrical and thermal conductivity and may ensure high bonding reliability in wire bonding processes.

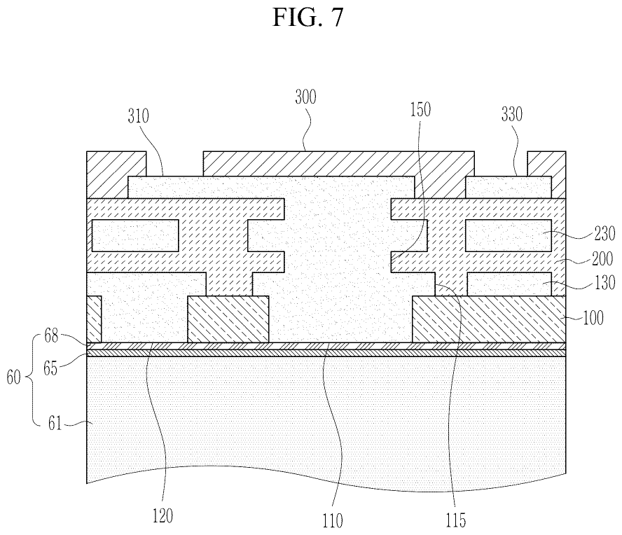

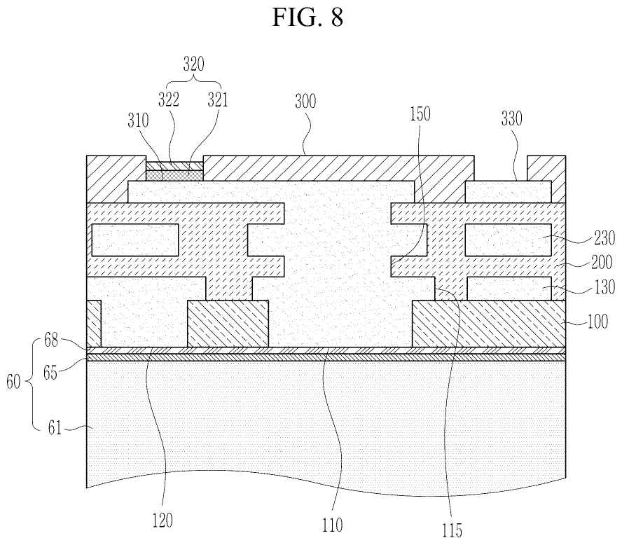

In the following manufacturing process of the circuit board 30, the plating layer 320 may be formed by electrolytic plating while electrically connecting a first copper layer 65 of a base substrate 60 and the first upper pad 310 (see FIG. 7 and FIG. 8). Unlike the conventional plating method using bus lines, this has the advantage of ensuring uniform plating quality without a separate bus line design, as the first copper layer 65 acts as a passage that supplies current evenly to all pads. The electroplating process enables precise thickness control and provides uniform metal deposition, resulting in high-quality pad surface treatment.

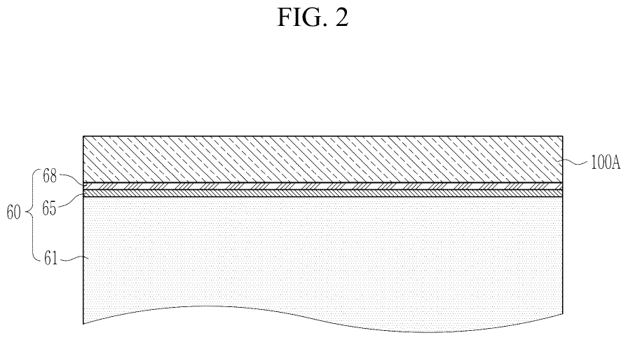

FIG. 2 to FIG. 9 are schematic process cross-sectional views illustrating a method for manufacturing a circuit board according to an embodiment.

Referring to FIG. 2, a structure of a base substrate 60 applied to the manufacturing process of a circuit board 30 is shown. The base substrate 60 may be composed of a detachable core substrate that is removed after the process is completed.

The base substrate 60 may include a core layer 61, and the core layer 61 may be composed of a composite sheet or a glass sheet impregnated with a glass material. A first copper layer 65 may be formed on an upper surface of the core layer 61, and a second copper layer 68 may be disposed on the first copper layer 65. The first copper layer 65 may be formed to a thickness of, for example, about 1.5 μm.

The second copper layer 68 may be formed primarily of copper material and may be bonded to the first copper layer 65 through a separating adhesive layer (not shown). The first copper layer 65 and the second copper layer 68 may be formed on the upper and lower surfaces of the core layer 61 of the base substrate 60, but for convenience of explanation, the lower surface structure is omitted and only the upper surface structure is illustrated and described.

A first insulating layer 100A may be laminated on the base substrate 60 through a lamination process. The first insulating layer 100 may be composed of materials selected from PID (photosensitive interlayer dielectric), PPG (Prepreg), ABF (Ajinomoto Build-up Layer), RCC (Resin Coated Copper), etc.

The material selection for the first insulating layer 100 may be determined by considering warpage prevention, thickness control, thermal stability, etc., depending on the specifications of the final product and the characteristics of the subsequent process. The lamination process may be performed to ensure adhesion between the first insulating layer 100 and the base substrate 60.

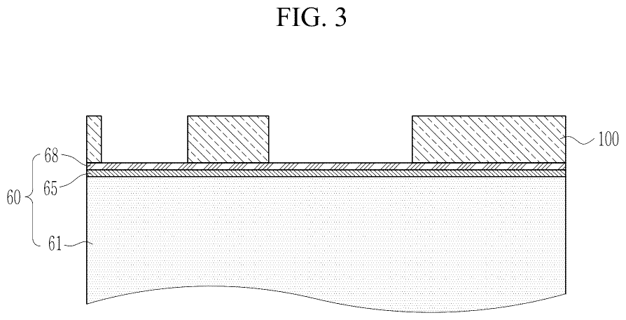

Referring to FIG. 3, the first insulating layer 100 is shown as a patterned first insulating layer 100 through a patterning process after lamination. In this process, the portion of the first insulating layer 100 where the ball pad or fiducial mark is formed may be opened to expose the underlying structure, and the open area of the first insulating layer 100 may be filled through an electrolytic plating process. Here, current may be supplied from the second copper layer 68.

When PID is selected as the material for the first insulating layer 100, the first insulating layer 100 may be patterned through a photoresist process so that the first insulating layer 100 is selectively removed and penetrated. Through this, the area where the ball pad or fiducial mark is to be formed in the first insulating layer 100 may be precisely penetrated.

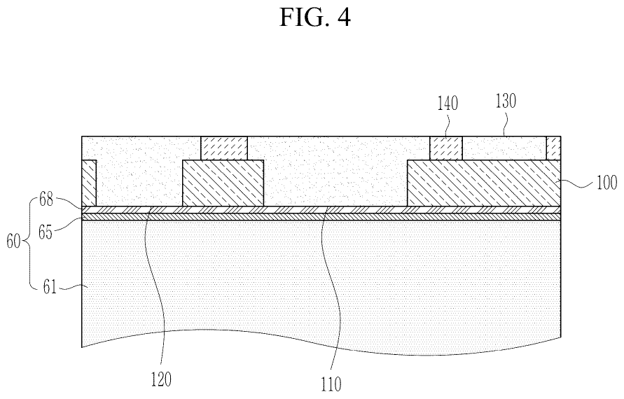

Referring to FIG. 4, a state in which a mask pattern 140 using a dry film resist is formed on the first insulating layer (100) is shown. The area opened with the mask pattern 140 may include a first area including a penetrated area of the first insulating layer 100 and a second area opening an upper surface of the first insulating layer 100.

In the first area, the area opened with the mask pattern 140 may be formed larger than the penetrated area of the first insulating layer 100. This may provide a structure in which the lower pads 110, 120 to be formed in a subsequent process extend along the sidewall of the first insulating layer 100 and extend to the upper surface of the first insulating layer 100. The mask pattern 140 may be formed of a photosensitive dry layer resist material, and a precise pattern may be implemented through an exposure and development process.

The lower pads 110, 120 may be formed through an electrolytic plating process in the penetrated area of the first insulating layer 100. The lower pads may include the first lower pad 110 to be a ball pad and the second lower pad 120 to be a fiducial mark.

In the second region, an area where the signal wiring 130 may be formed on the first insulating layer 100 may be defined. The signal wiring 130 may be formed of a conductive metal such as copper and may function as an electrical signal transmission path within the circuit board 30.

Before an electroplating process, an electroless plating layer (not shown) for use as an electroplating seed may be formed on the mask pattern 140, the first insulating layer 100, and the second copper layer 68 exposed by the first insulating layer 100.

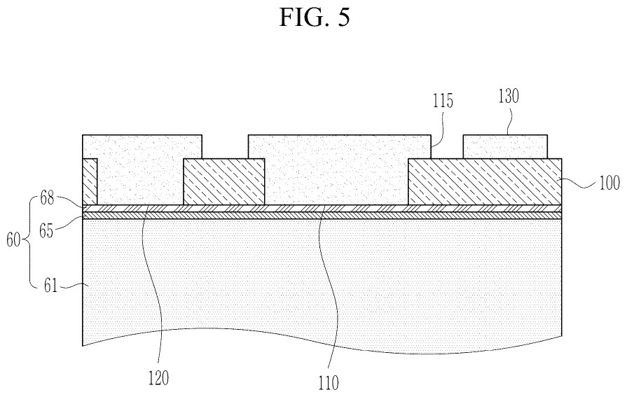

Referring to FIG. 5, it shows a state where the mask pattern 140 has been removed. The first lower pad 110 and the second lower pad 120 may have the extension portion 115 extending on the first insulating layer 100. The first lower pad 110 may be used as a ball pad for signal connection, and the second lower pad 120 may be used as an assembly fiducial mark. The lower pads 110 and 120 may be formed of a conductive metal such as copper, nickel, or gold.

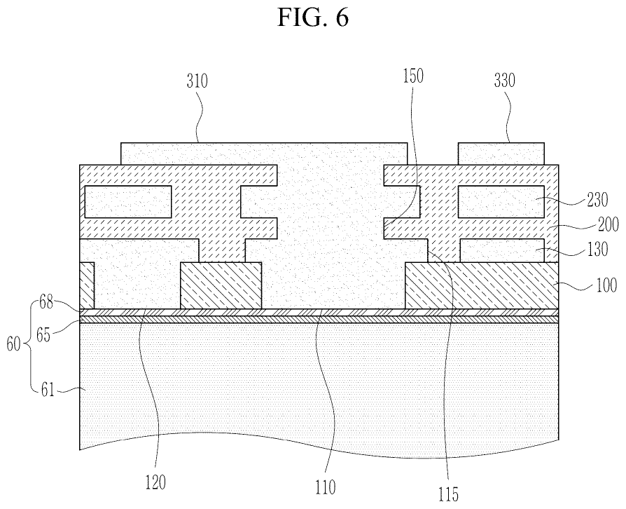

Referring to FIG. 6, it shows a state in which a signal pattern or bonding pad of the upper layer is additionally formed through a build-up process after the formation of the lower pad and signal wiring. In the build-up process, multiple layers may be stacked as needed, and the pattern formation and plating processes may be repeated for each layer.

In the illustrated embodiment, an example is shown in which a second insulating layer 200 including two layers of insulating layers is formed on the first signal wiring 130, and a circuit layer including a second signal wiring 230 is formed. However, in an actual product, the circuit configuration may be configured with more or fewer layers depending on the required circuit configuration.

The first upper pad 310 and the second upper pad 330 may be formed on a top layer. The first upper pad 310 may be electrically connected to the first lower pad 110 through the via 150. The via 150 may be a filled via, filled with a conductive metal such as copper, and may serve as an electrical connection path between layers. The first upper pad 310 may be used as a bond finger or solder ball pad for connection to a semiconductor chip, and the second upper pad 330 may be used as a pad for power supply or ground connection.

Referring to FIG. 7, it shows a state in which the protective layer 300 is formed by covering the first upper pad 310 and the second upper pad 330. The protective layer 300 may serve to protect the circuit from the external environment and limit a soldering area. The protective layer 300 may be composed of a solder resist and may be selected from insulating materials such as PID (photosensitive interlayer dielectric), ABF (Ajinomoto Build-up Layer), and RCC (Resin Coated Copper).

The protective layer 300 may be patterned and opened to expose portions of each of the first upper pad 310 and the second upper pad 330. Electrical connections to semiconductor chips or other electronic components may be made through these open areas. The protective layer 300 may be composed of a photosensitive material, enabling precise patterning through exposure and development processes.

Referring to FIG. 8, it shows a state in which the plating layer 320 is formed on the first upper pad 310 exposed from the protective layer 300. Organic Solderability Preservative (OSP) surface treatment may be performed on the second upper pad 330 that does not require plating. These differentiated surface treatments may be applied according to the function and required characteristics of each pad.

The first upper pad 310 is electrically connected to the first lower pad 110 through a via 150, and the first lower pad 110 is connected to the second copper layer 68 and the first copper layer 65 of the base substrate 60. By utilizing these structural characteristics, electrolytic plating may be performed by forming an electrical connection with the first upper pad 310 through the first copper layer 65 of the base substrate 60.

Ni/Au plating may be performed on the upper pad 310 through electrolytic plating to form the plating layer 320 composed of the nickel (Ni) plating layer 321 and the gold (Au) plating layer 322. The nickel plating layer 321 acts as a diffusion barrier between copper and gold, and the gold plating layer 322 may provide oxidation prevention and excellent wire bonding properties.

On the second upper pad 330, pad surface treatment may be performed by coating an OSP drug. The OSP surface treatment may prevent oxidation and maintain solder wettability by coating the surface of the copper pad with an organic compound, and is a surface treatment method suitable for pads that do not require a plating process.

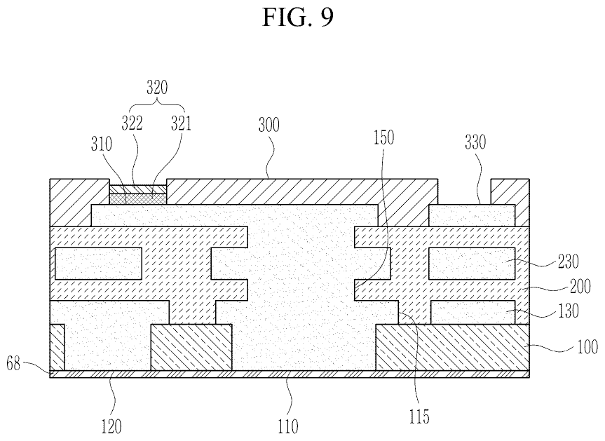

Referring to FIG. 9, it shows a state in which the core layer 61 of the base substrate 60 is separated after the circuit board 30 forming process. In base substrate 60, when a separable adhesive layer (not shown) that bonds the first copper layer 65 and the second copper layer 68 is separated, the core layer 61 and the first copper layer 65 may be separated from the formed circuit board 30.

After the core layer 61 is separated, the second copper layer 68 may remain under the first insulating layer 100. This separation process may be performed by methods such as heat treatment, mechanical peeling, or chemical treatment, and an appropriate separation method may be selected depending on the characteristics of the separable adhesive layer.

The circuit board 30 with the core layer 61 and the first copper layer 65 removed may have a thinner and lighter structure, which may provide characteristics suitable for small electronic devices. In addition, the separation of the base substrate 60 may improve the heat dissipation characteristics and electrical performance of the electronic device, and increase the mechanical flexibility.

Referring to FIG. 1, the lower surface of the formed circuit board 30 may be etched to remove the second copper layer 68. By removing the second copper layer 68, the first lower pad 110 and the second lower pad 120 may be electrically isolated from each other. This may provide the effect of preventing circuit interference by securing electrical independence between pads.

Etching may be performed through flash etching or quick etching. Flash etching or quick etching is a surface etching process that takes place over a short period of time and has the advantage of being able to precisely remove only the necessary portion without excessive etching. By performing flash etching or quick etching, the second copper layer 68 on the lower surface of the first insulating layer 100 may be completely removed. Furthermore, lower edge portions of the first lower pad 110 and the second lower pad 120 connected to the second copper layer 68 may also be partially eroded.

Accordingly, the first lower pad 110 and the second lower pad 120 may be recessed from the surface of the first insulating layer 100 by a predetermined depth (d). The depth (d) may be formed to be 2 μm or more to improve the mounting reliability of electronic components, and may generally be adjusted within the range of 1 to 5 μm. This recessed structure may improve the flatness of the pad surface and provide the effect of protecting the pad from external impact.

The first lower pad 110 is configured as an integral part including a portion extending on the first insulating layer 100, so that even if the thickness of the circuit metal layer is reduced to reduce the circuit board thickness, the minimum copper thickness (t) required for the Board Level Test standard may be secured. This structure may provide the advantage of maintaining mechanical stability while reducing the thickness of the circuit board.

Afterwards, OSP surface treatment may be performed on the exposed surfaces of the first lower pad 110 and the second lower pad 120. OSP treatment may prevent oxidation of copper pads and maintain solder wettability for a long time, thereby improving the reliability of subsequent mounting processes. The first lower pad 110 may be made of copper or copper alloy and functions as an electronic component mounting surface, and the second lower pad 120 is designed with a vertical structure and may function as a fiducial mark for position confirmation during the assembly process.

According to the method for manufacturing a circuit board according to the embodiment described above, an improvement in manufacturing capability for reducing the thickness of the circuit board may be achieved by using a double separable core. In addition, the electrolytic nickel/gold plating manufacturing process may be effectively implemented in designs without bus lines, which are emerging as a result of the demand for increased design density.

By utilizing a coreless structure, the circuit board process may be designed to enable electrolytic nickel/gold plating without designing separate bus lines within the unit. This can provide simplification of the manufacturing process and cost reduction effects by omitting the existing bus line design and removal processes.

In addition, since the separation of the detachable core is performed after the protective layer formation and surface treatment have been performed, a stable process design is possible from manufacturing issues such as circuit board damage and snagging due to circuit board thickness reduction. This manufacturing method may provide the advantage of ensuring high yield and reliability even in mass production of ultra-thin circuit board.

While embodiments of the present invention have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising:
a first insulating layer;
a lower pad exposed from the first insulating layer, wherein an exposed surface has a depth recessed from a surface of the first insulating layer;
a second insulating layer disposed on the first insulating layer;
an upper pad disposed on the second insulating layer;
a via penetrating the second insulating layer, and connecting the lower pad and the upper pad; and
a plating layer disposed on the upper pad.

2. The circuit board of claim 1, wherein
the plating layer comprises a nickel plating layer and a gold plating layer.

3. The circuit board of claim 1, further comprising
a protective layer disposed on the second insulating layer and covering the upper pad.

4. The circuit board of claim 3, wherein
the protective layer is penetrated to expose a portion of the upper pad, and the plating layer is disposed on an exposed upper pad.

5. The circuit board of claim 1, wherein
the first insulating layer and the second insulating layer comprise different insulating materials.

6. The circuit board of claim 1, wherein
the upper pad comprises a first upper pad and a second upper pad disposed apart from each other on the second insulating layer, and
the first upper pad is connected to the via.

7. The circuit board of claim 6, wherein
the plating layer is disposed on the first upper pad.

8. The circuit board of claim 6, wherein
the lower pad comprises a first lower pad and a second lower pad spaced from each other by the first insulating layer, and
the first lower pad is connected to the via.

9. The circuit board of claim 8, wherein
the first lower pad comprises a ball pad.

10. The circuit board of claim 8, wherein:
the second lower pad comprises a fiducial mark.

11. The circuit board of claim 1, wherein
the lower pad has an extension portion that is larger than a width of a portion embedded in the first insulating layer and extends on the first insulating layer.

12. A manufacturing method of a circuit board, comprising:
forming a first insulating layer on a copper layer of a base substrate;
forming a lower pad that penetrates the first insulating layer and is connected to the copper layer;
forming a second insulating layer on the first insulating layer;
forming a via penetrating the second insulating layer and connected to the lower pad, and an upper pad disposed on the second insulating layer and connected to the via; and
forming a plating layer on the upper pad by applying electricity to the copper layer.

13. The manufacturing method of claim 12, further comprising
removing the base substrate from the first insulating layer.

14. The manufacturing method of claim 12, further comprising
removing the copper layer by etching.

15. The manufacturing method of claim 12, wherein
the base substrate comprises a detachable core substrate.

16. The manufacturing method of claim 12, wherein
forming of the lower pad comprises forming an extension portion that is larger than a width of a portion embedded in the first insulating layer and extends on the first insulating layer.

17. The manufacturing method of claim 12, further comprising forming a protective layer to cover the upper pad on the second insulating layer.

18. The manufacturing method of claim 17, wherein
forming of the plating layer comprises conducting electroplating on an area where the upper pad is exposed by patterning the protective layer.

19. The manufacturing method of claim 12, wherein
forming of the plating layer comprises plating a nickel plating layer and a gold plating layer.
